(19) United States
(12) Patent Application Publication
(10) Pub. No.: US 2024/0250652 A1
(43) Pub. Date: Jul. 25, 2024

(54) OUTPUT CONTROL CIRCUIT, CONTROLLER, AND AIR CONDITIONER

(71) Applicants: SHANGHAI MEICON INTELLIGENT CONSTRUCTION CO., LTD., Shanghai (CN); GD MIDEA HEATING & VENTILATING EQUIPMENT CO., LTD., Foshan, Guangdong (CN)

(72) Inventors: Zhen ZHAO, Shanghai (CN); Dayou YANG, Shanghai (CN); Jie YAN, Shanghai (CN)

(73) Assignees: SHANGHAI KONG INTELLIGENT BUILDING CO., LTD., Shanghai (CN); GD MIDEA HEATING & VENTILATING EQUIPMENT CO., LTD., Foshan, Guangdong (CN)

(21) Appl. No.: 18/564,280

(22) PCT Filed: Aug. 2, 2022
(86) PCT No.: PCT/CN2022/109802

§ 371 Date: Nov. 27, 2023

(30) Foreign Application Priority Data
Nov. 1, 2021 (CN) 202111284433.0

(51) Int. Cl. H03F 3/45; H03F 1/52

(52) U.S. Cl. CPC H03F 3/45475; H03F 1/52; H03F 2200/261; H03F 2203/45138

(57) ABSTRACT

An output control circuit, a controller, and an air conditioner are provided. The output control circuit includes a signal input end, a first amplification module, a first power module, a first resistor, a second amplification module, a switch module, and a signal output end. A first input end of the first amplification module is connected to the signal input end. A first input end of the first power module is connected to an output end of the first amplification module and a second input end is connected to a first direct-current voltage source. A first end of the first resistor is connected to an output end of the first power module. A first input end of the second amplification module is connected to the first end of the first resistor and a second input end is connected to a second end of the first resistor.

### CROSS-REFERENCE TO RELATED APPLICATION

This application claims priority to Chinese Patent Application Serial No. 202111284433.0, filed with the National Intellectual Property Administration of PRC on Nov. 1, 2021, the entire contents of which are incorporated herein by reference.

### FIELD

The present disclosure relates to the field of electronic technology, and particularly relates to an output control circuit, a controller and an air conditioner.

### BACKGROUND

With the rapid development of industrial automation, it has been increasing applied of a controller like Programmable Logic Controller (PLC) and a Direct Digital Control (DDC) in various fields such as industry, transportation, and buildings. With the intelligentization upgrading of the controller, there is a higher function demand on an output control circuit of the controller, for example, switching different functions of the output control circuit as desired, achieving various signal outputs such as an output with a digital quantity and an output with an analog quantity.

Therefore, it has become an urgent problem to be solved on how to enhance universality, safety, and reliability for the output control circuit.

### SUMMARY

The present disclosure aims to solve at least one of the technical problems in the related art to a certain degree.

In view of the above, a first object of the present disclosure is to provide an output control circuit, so as to further achieve intelligentization and remote configuration by software control, enabling the controller to switch different functions of an output signal, and enhancing universality, safety, and reliability for the output control circuit.

A second object of the present disclosure is to provide a controller.

A third object of the present disclosure is to provide an air conditioner.

In order to achieve the above objects, in a first aspect, the present disclosure provides in embodiments an output control circuit, wherein the output control circuit is arranged in a controller, and the output control circuit includes: a signal input end, configured to input a voltage input signal; a first amplification module, wherein a first input end of the first amplification module is connected to the signal input end; a first power module, wherein a first end of the first power module is connected to an output end of the first amplification module; and a second end of the first power module is connected to a first direct-current voltage source; a first resistor, wherein a first end of the first resistor is connected to a third end of the first power module; a second amplification module, wherein a first input end of the second amplification module is connected to the first end of the first resistor; and a second input end of the second amplification module is connected to a second end of the first resistor; a switch module, wherein the switch module is connected to the second end of the first resistor, an output end of the second amplification module, and a second input end of the first amplification module, respectively; and the switch module is configured to switch between a first connection and a second connection, wherein the first connection is between the second end of the first resistor and the second input end of the first amplification module; and the second connection is between the output end of the second amplification module and the second input end of the first amplification module; and a signal output end, wherein the signal output end is connected to the second end of the first resistor, and configured to output a digital quantity of a first voltage output signal, an analog quantity of a second voltage output signal, and an analog quantity of a current output signal.

According to embodiments of the present disclosure, the output control circuit includes: the signal output end, the signal input end, the first amplification module, the first power module, the first resistor, the second amplification module and the switch module; the voltage input signal is inputted from the signal input end; the first input end of the first amplification module is connected to the signal input end; the first end of the first power module is connected to the output end of the first amplification module; the second end of the first power module is connected to the first direct-current voltage source; the first end of the first resistor is connected to the third end of the first power supply; the second end of the first resistor is connected to the signal output end; the first input end of the second amplification module is connected to the first end of the first resistor; the second input end of the second amplification module is connected to the second end of the first resistor; the switch module is connected to the second end of the first resistor, the output end of the second amplification module, and the second input end of the first amplification module, respectively; the switch module is configured to switch between the first connection and the second connection, where the first connection is between the second end of the first resistor and the second input end of the first amplification module, while the second connection is between the output end of the second amplification module and the second input end of the first amplification module; and the digital quantity of the first voltage output signal, the analog quantity of the second voltage output signal, and the analog quantity of the current output signal are outputted from the signal output end. As such, the output control circuit further achieves intelligentization and remote configuration by software control, thus enabling the controller to switch different functions of the output signal, and enhancing universality, safety, and reliability for the output control circuit.

In addition, the output control circuit provided in embodiments of the first aspect of the present disclosure may further have the following additional technical features.

In an embodiment of the present disclosure, the first amplification module includes a first operational amplifier, wherein a non-inverting input end of the first operational amplifier is connected to the signal input end; and an output end of the first operational amplifier is connected to the first end of the first power module; a first capacitor, wherein a first end of the first capacitor is connected to the output end of the first operational amplifier, and a second end of the first capacitor is connected to an inverting input end of the first operational amplifier; and a second resistor, wherein a first end of the second resistor is connected to the inverting input end of the first operational amplifier, and a second end of the second resistor is connected to the switch module.

In an embodiment of the present disclosure, the output control circuit further includes an overcurrent protection module, wherein the second end of the first power module is connected to the first direct-current voltage source through the overcurrent protection module.

In an embodiment of the present disclosure, the overcurrent protection module includes: a voltage stabilizer or current limiter, wherein a first end of the voltage stabilizer or current limiter is connected to the first direct-current voltage source; and a second end of the voltage stabilizer or current limiter is connected to the second end of the first power module; and a third resistor, wherein the second end of the voltage stabilizer or current limiter is connected to a third end of the voltage stabilizer or current limiter through the third resistor.

In an embodiment of the present disclosure, the second amplification module includes: a fourth resistor; a fifth resistor; a second operational amplifier, wherein a non-inverting input end of the second operational amplifier is connected to the first end of the first resistor through the fourth resistor; an inverting input end of the second operational amplifier is connected to the second end of the first resistor through the fifth resistor; and an output end of the second operational amplifier is connected to the switch module; a sixth resistor, wherein a first end of the sixth resistor is grounded; a second end of the sixth resistor is connected to the non-inverting input end of the second operational amplifier; a seventh resistor, wherein a first end of the seventh resistor is connected to the output end of the second operational amplifier; and a second end of the seventh resistor is connected to the inverting input end of the second operational amplifier; and a second capacity, wherein a first end of the second capacitor is connected to the output end of the second operational amplifier; and a second end of the second capacitor is connected to the inverting input end of the second operational amplifier.

In an embodiment of the present disclosure, the switch module includes: a first switch unit, wherein the first switch unit is connected to the second end of the first resistor and the second input end of the first amplification module, respectively; a second switch unit, wherein the second switch unit is connected to the output end of the second amplification module and the second input end of the first amplification module, respectively; and a control unit, wherein the control unit is connected to the first switch unit and the second switch unit, respectively; the control unit is configured to: in response to a control signal inputted, control the first switch unit to enable or disenable the first connection between the second end of the first resistor and the second input end of the first amplification module; or control the second switch unit to enable or disenable the second connection between the output end of the second amplification module and the second input end of the first amplification module.

In an embodiment of the present disclosure, the first switch unit includes a first solid-state relay, wherein an input end of the first solid-state relay is connected to the second end of the first resistor; an output end of the first solid-state relay is connected to the second input end of the first amplification module; an input control end of the first solid-state relay is connected to the control unit; and an output control end of the first solid-state relay is grounded.

In an embodiment of the present disclosure, the second switch unit includes a second solid-state relay, wherein an input end of the second solid-state relay is connected to the output end of the second amplification module; an output end of the second solid-state relay is connected to the second input end of the first amplification module; an input control end of the second solid-state relay is connected to the control unit; and an output control end of the second solid-state relay is grounded.

In an embodiment of the present disclosure, the control unit includes: a control signal input end, configured to input the control signal; a first transistor, wherein a control end of the first transistor is connected to the control signal input end; a first end of the first transistor is connected to the first switch unit; and a second end of the first transistor is grounded; an eighth resistor, wherein a first end of the eighth resistor is connected to a second direct-current voltage source; and a second end of the eighth resistor is connected to the first end of the first transistor; and a second transistor, wherein a control end of the second transistor is connected to the control signal input end; a first end of the second transistor is connected to a third direct-current voltage source; and a second end of the second transistor is connected to the second switch unit.

In an embodiment of the present disclosure, the output control circuit further includes a diode, wherein a positive electrode of the diode is grounded; and a negative electrode of the diode is connected to the signal output end.

In an embodiment of the present disclosure, the output control circuit further includes a filtration module, wherein the first input end of the first amplification module is connected to the signal input end through the filtration module.

In an embodiment of the present disclosure, the output control circuit further includes: a second power module, wherein a first end of the second power module is connected to the output end of the first amplification module; and a second end of the second power module is connected to the second end of the first power module; and a ninth resistor, wherein a first end of the ninth resistor is connected to a third end of the second power module; and a second end of the ninth resistor is connected to the signal output end, wherein the second amplification module further includes: a tenth resistor, wherein a first end of the tenth resistor is connected to the first end of the ninth resistor; and a second end of the tenth resistor is connected to the non-inverting input end of the second operational amplifier.

To achieve the above objects, in a second aspect, the present disclosure provides in embodiments a controller, including the output control circuit as described in any of the above embodiments of the first aspect of the present disclosure.

According to embodiments of the present disclosure, the controller further achieves intelligentization and remote configuration by software control, enabling the controller to switch different functions of the output signal, and enhancing universality, safety, and reliability for the output control circuit.

To achieve the above objects, in a third aspect, the present disclosure provides in embodiments an air conditioner, including the controller as described in any of the above embodiments of the second aspect of the present disclosure.

According to embodiments of the present disclosure, the air conditioner further achieves intelligentization and remote configuration by software control, enabling the controller to switch different functions of the output signal, and enhancing universality, safety, and reliability for the output control circuit

The additional aspects and advantages of the present disclosure will be partially provided in the following description, which will become apparent from the following description or learned through the practice of the present disclosure.

### BRIEF DESCRIPTION OF THE DRAWINGS

The additional aspects and advantages of the present disclosure will be partially provided in the following description, which will become apparent from the following description or learned through the practice of the present disclosure.

FIG. 1 is a schematic diagram showing an output control circuit according to an embodiment of the present disclosure;

FIG. 2 is a schematic diagram showing an overcurrent protection module of an output control circuit according to an embodiment of the present disclosure;

FIG. 3 is a schematic diagram showing a first amplification module of an output control circuit according to an embodiment of the present disclosure;

FIG. 4 is a schematic diagram showing a second amplification module of an output control circuit according to an embodiment of the present disclosure;

FIG. 5 is a schematic diagram showing a switch module of an output control circuit according to an embodiment of the present disclosure;

FIG. 6 is a schematic diagram showing a control unit of an output control circuit according to an embodiment of the present disclosure;

FIG. 7 is a simplified circuit diagram showing an output control circuit in a voltage output mode according to an embodiment of the present disclosure;

FIG. 8 is a simplified circuit diagram showing an output control circuit in a current output mode according to an embodiment of the present disclosure;

FIG. 9 is an overall schematic diagram showing an output control circuit according to an embodiment of the present disclosure;

FIG. 10 is an overall schematic diagram showing an output control circuit according to another embodiment of the present disclosure;

FIG. 11 is a block diagram showing a controller according to an embodiment of the present disclosure; and

FIG. 12 is a block diagram showing an air conditioner according to an embodiment of the present disclosure; and

### DETAILED DESCRIPTION

Reference will be made in details to embodiments of the present disclosure. The same or similar elements and the elements having same or similar functions are denoted by like reference numerals throughout the descriptions. The embodiments described herein with reference to drawings are explanatory, illustrative, and used to generally understand the present disclosure. The embodiments shall not be construed to limit the present disclosure.

With reference to the accompany drawings, an output control circuit, a controller, and an air conditioner in embodiments of the present disclosure are described below.

FIG. 1 is a schematic diagram showing an output control circuit according to an embodiment of the present disclosure.

As shown in FIG. 1, in an embodiment of the present disclosure, the output control circuit (1) may specifically include: a signal input end (in), a signal output end (out), a first amplification module (10), a first resistor (R1), a second amplification module (20), a switch module (30), and a first power module (40).

In specific, the signal input end (in) is configured to input a voltage input signal, for example a voltage input signal with an analog quantity at 0-10 V, or a voltage input signal with a digital quantity at 12 V. The first amplification module (10) includes a first input end, a second input end and an output end, where the first input end of the first amplification module (10) is connected to the signal input end (in); the second input end of the first amplification module (10) is connected to the switch module (30), and the output end of the first amplification module (10) is connected to a first end of the first power module (40), where a second end of the first power module (40) is connected to a first direct-current power supply VDD1 (such as a direct-current power supply at 12 V to 14 V); and a third end of the first power module (40) is connected to a first end of the first resistor (R1), where a second end of the first resistor (R1) is connected to the signal output end (out) and the switch module (30), where the first amplification module (10) may be configured to amplify the voltage input signal, for example, when the voltage input signal is lower than 10 V, the first amplification module (10) may output an amplified voltage signal at 10 V for the first end of the first power module (40). The second amplification module (20) includes a first input end, a second input end and an output end, where the first input end of the second amplification module (20) is connected to the first end of the first resistor (R1); the second input end of the second amplification module (20) is connected to the second end of the first resistor (R1); and the output end of the second amplification module (20) is connected to the switch module (30). The switch module (30) is configured to switch between a first connection and a second connection, wherein the first connection is between the second end of the first resistor (R1) and the second input end of the first amplification module (10), and the second connection is between the output end of the second amplification module (20) and the second input end of the first amplification module (10). The signal output end (out) is configured to output a digital quantity of a first voltage output signal, an analog quantity of a second voltage output signal, and an analog quantity of a current output signal. In specific, the digital quantity of the first voltage output signal may be a voltage output signal at 12 V; the analog quantity of the second voltage output signal may be a voltage output signal at 0-10 V; and the analog quantity of the current output signal may be a current output signal at 0-20 mA.

For example, when it is required to output the analog quantity of the second voltage output signal (such as the voltage output signal at 0-10 V) from the signal output end (out), the voltage input signal inputted from the signal input end (in) is controlled to be the voltage input signal with the analog quantity at 0-10 V; and the first connection between the second end of the first resistor (R1) and the second input end of the first amplification module (10) is enabled; while the second connection between the output end of the second amplification module (20) and the second input end of the first amplification module (10) is disenabled, accordingly the first amplification module (10) and the first power module (40) constitute an emitter follower circuit, so that the analog quantity of the second voltage output signal (such as the voltage output signal at 0-10 V) is outputted from the signal output end (out).

When it is required to output the digital quantity of the first voltage output signal (such as the voltage output signal at 12 V) from the signal output end (out), the voltage input signal inputted from the signal input end (in) is controlled to be the voltage input signal with the digital quantity at 12 V; and similarly, the first connection between the second end of the first resistor (R1) and the second input end of the first amplification module (10) is enabled; while the second connection between the output end of the second amplification module (20) and the second input end of the first amplification module (10) is disenabled, accordingly the first amplification module (10) and the first power module (40) constitute the emitter follower circuit, so that the digital quantity of the first voltage output signal (such as, the voltage output signal at 12 V) is outputted from the signal output end (out).

When it is required to output the analog quantity of the current output signal (such as the current output signal at 0-20 mA) from the signal output end (out), the voltage input signal inputted from the signal input end (in) is controlled to be the voltage input signal with the analog quantity at 0-10 V; and the first connection between the second end of the first resistor (R1) and the second input end of the first amplification module (10) is disenabled; while the second connection between the output end of the second amplification module (20) and the second input end of the first amplification module (10) is enabled, so that the analog quantity of the current output signal (such as the current output signal at 0-20 mA) is outputted from the signal output end (out).

As such, the output control circuit, by means of controlling the output control circuit with software, further achieves intelligentization and remote configuration, thus enabling the controller to switch different functions of the output signal, and enhancing universality, safety, and reliability for the output control circuit.

With reference to FIGS. 2-9, the output control circuit is specifically illustrated below.

It should be noted that the first power module (40) may be composed of a triode or a Metal-Oxide-Semiconductor (MOS) transistor, which is not limited herein particularly. In embodiments of the present disclosure as shown in FIGS. 7-9, for convenient illustration, illustration is made by taking a first triode (Q1) serving as the first power module (40) as an example, where a base electrode of the first triode (Q1) serves as the first end of the first power module (40); a collecting electrode of the first triode (Q1) serves as the second end of the first power module (40); and an emitting electrode of the first triode (Q1) serves as the third end of the first power module (40).

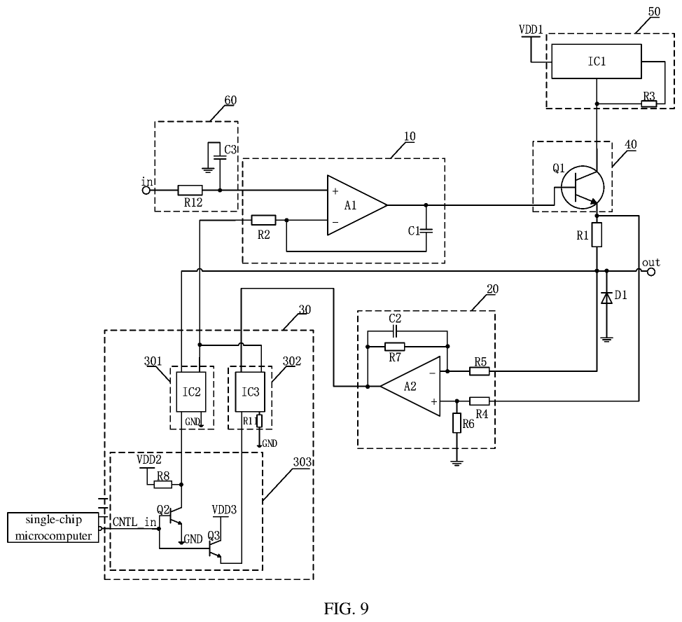

As shown in FIGS. 2 and 9, the output control circuit (1) may further include an overcurrent protection module (50), where the first triode (Q1) is connected to the first direct-current power supply VDD1 through the overcurrent protection module (50), thereby providing overcurrent protection on the first triode (Q1) upon a short circuit of the signal output end (out) due to user's mis-operation.

As a possible embodiment, as shown in FIG. 2, the overcurrent protection module (50) may include a voltage stabilizer or current limiter (IC1) and a third resistor (R3), where the voltage stabilizer or current limiter (IC1) is a three-end voltage stabilizer or current limiter, a first end of the voltage stabilizer or current limiter (IC1) is connected to the first direct-current voltage source VDD1, a second end of the voltage stabilizer or current limiter (IC1) is connected to the collecting electrode of the first triode (Q1); and the second end of the voltage stabilizer or current limiter (IC1) is connected to a third end of the voltage stabilizer or current limiter (IC1) through the third resistor (R3).

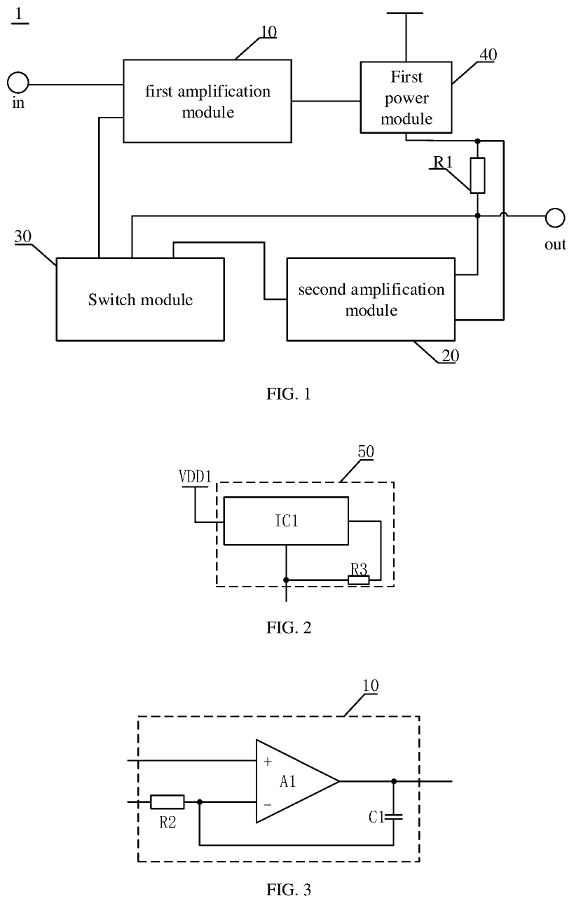

As shown in FIGS. 3 and 9, the first amplification module (10) may include: a first operational amplifier (A1), a first capacitor (C1), and a second resistor (R2). In specific, a non-inverting input end of the first operational amplifier (A1), serving as the first input end of the first amplification module (10), is connected to the signal input end (in); an output end of the first operational amplifier (A1), serving as the output end of the first amplification module (10), is connected to the base electrode of the first triode (Q1); an inverting input end of the first operational amplifier (A1), serving as the second input end of the first amplification module (10), is connected to a first end of the second resistor (R2); and a second end of the second resistor (R2) is connected to the switch module (30). A first end of the first capacitor (C1) is connected to the output end of the first operational amplifier (A1); and a second end of the first capacitor (C1) is connected to the inverting input end of the first operational amplifier (A1).

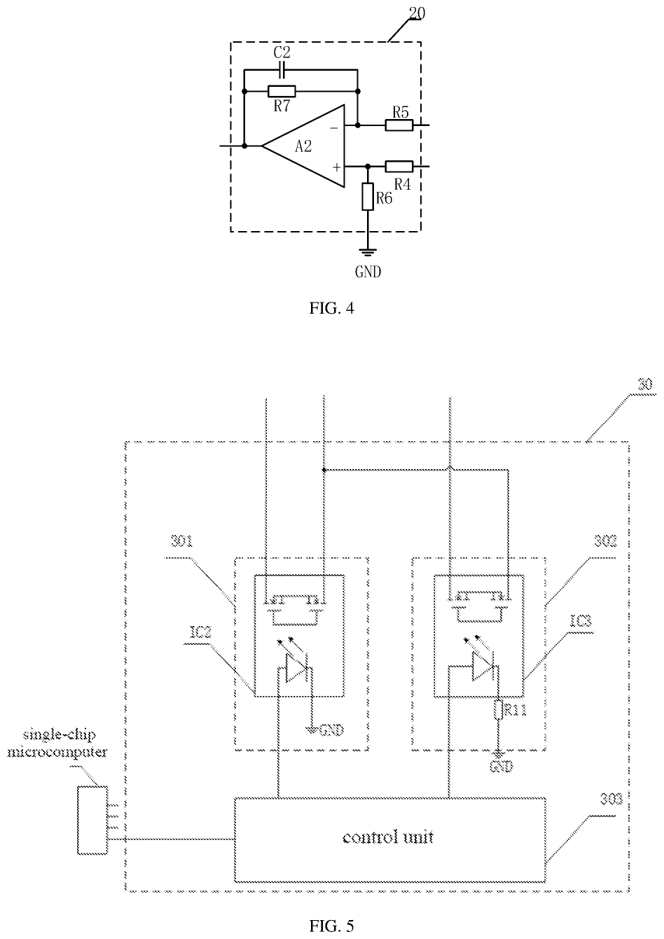

As shown in FIGS. 4 and 9, the second amplification module (20) may include: a fourth resistor (R4), a fifth resistor (R5), a second operational amplifier (A2), a sixth resistor (R6), a seventh resistor (R7), and a second capacitor (C2). In specific, a non-inverting input end of the second operational amplifier (A2) is connected to a first end of the fourth resistor (R4); a second end of the fourth resistor (R4), serving as the first input end of the second amplification module (20), is connected to the first end of the first resistor (R1); an inverting input end of the second operational amplifier (A2) is connected to a first end of the fifth resistor (R5); a second end of the fifth resistor (R5), serving as the second input end of the second amplification module (20), is connected to the second end of the first resistor (R1); and an output end of the second operational amplifier (A2), serving as the output end of the second amplification module (20), is connected to the switch module (30). A first end of the sixth resistor (R6) is grounded (GND); and a second end of the sixth resistor (R6) is connected to the non-inverting input end of the second operational amplifier (A2). A first end of the seventh resistor (R7) is connected to the output end of the second operational amplifier (A2); and a second end of the seventh resistor (R7) is connected to the inverting input end of the second operational amplifier (A2). A first end of the second capacitor (C2) is connected to the output end of the second operational amplifier (A2); and a second end of the second capacitor (C2) is connected to the inverting input end of the second operational amplifier (A2).

As shown in FIGS. 5 and 9, the switch module (30) may include: a first switch unit (301), a second switch unit (302), and a control unit (303). In specific, the second end of the first resistor (R1) is connected to the switch module (30), specifically may be connected to the first switch unit (301) in the switch module (30). The second input end of the first amplification module (10) is connected to the switch module (30), specifically may be connected to the first switch unit (301) and the second switch unit (302) in the switch module (30). The output end of the second amplification module (20) is connected to the switch module (30), specifically may be connected to the second switch unit (302) in the switch module (30). The control unit (303) is connected to the first switch unit (301) and the second switch unit (302) respectively, and configured to: in response to the control signal inputted, control the first switch unit (301) to enable or disenable the first connection between the second end of the first resistor (R1) and the second input end of the first amplification module (10); and control the second switch unit (302) to enable or disenable the second connection between the output end of the second amplification module (20) and the second input end of the first amplification module (10).

In an embodiment of the present disclosure, the first switch unit (301) may include, but not limited to, a first solid-state relay (IC2), and etc., where the first solid-state relay (IC2) includes an input end, an output end, an input control end, and an output control end. As shown in FIGS. 5 and 9, in the first switch unit (301), the input end of the first solid-state relay (IC2) is connected to the second end of the first resistor (R1); the output end of the first solid-state relay (IC2) is connected to the second input end of the first amplification module (10); the input control end of the first solid-state relay (IC2) is connected to the control unit (303); and the output control end of the first solid-state relay (IC2) is grounded (GND).

In an embodiment of the present disclosure, the second switch unit (302) may include, but not limited to, a second solid-state relay (IC3), and etc., where the second solid-state relay (IC3) includes an input end, an output end, an input control end, and an output control end. As shown in FIGS. 5 and 9, in the second switch unit (302), the input end of the second solid-state relay (IC3) is connected to the output end of the second amplification module (20); the output end of the second solid-state relay (IC3) is connected to the second input end of the first amplification module (10); the input control end of the second solid-state relay (IC3) is connected to the control unit (303); and the output control end of the second solid-state relay (IC3) is grounded (GND) or may be grounded (GND) through an eleventh resistor (R11).

It should be noted that the first switch unit (301) and the second switch unit (302) each are not limited to a solid-state relay, which may also be a slide switch and a wire jumper, or may also be an electromagnetic relay, etc. The respective input control ends of the first switch unit (301) and the second switch unit (302) are controlled by an IO pin of a single-chip microcomputer, and the first switch unit (301) and the second switch unit (302) are then controlled by software.

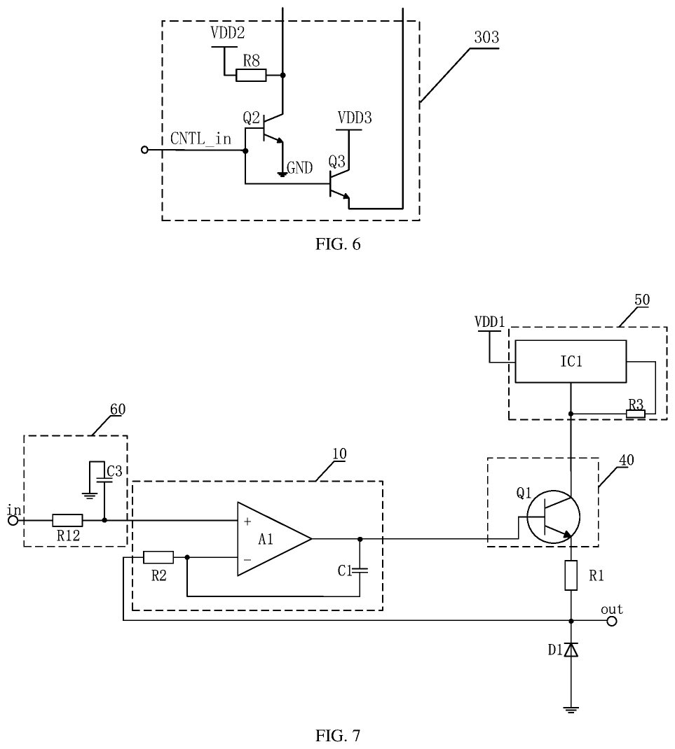

As shown in FIGS. 6 and 9, the control unit (303) may include: a control signal input end (CNTL-in), a first transistor (Q2), an eighth resistor (R8), and a second transistor (Q3). In specific, the control signal is generated by the single-chip microcomputer, and is inputted to the control unit (303) from the control signal input end (CNTL-in). A control end of the first transistor (Q2) is connected to the control signal input end (CNTL-in); a first end of the first transistor (Q2) is connected to the first switch unit (301), specifically may be connected to the input control end of the first solid-state relay (IC2); and a second end of the first transistor (Q2) is grounded. A first end of the eighth resistor (R8) is connected to a second direct-current voltage source VDD2; and a second end of the eighth resistor (R8) is connected to the first end of the first transistor (Q2). A control end of the second transistor (Q3) is connected to the control signal input end (CNTL-in); a first end of the second transistor (Q3) is connected to a third direct-current voltage source VDD3; and a second end of the second transistor (Q3) is connected to the second switch unit (302), specifically may be connected to the input control end of the second solid-state relay (IC3).

In some embodiments, the control signal may be outputted by the single-chip microcomputer to the control signal input end (CNTL-in), so as to control the first transistor (Q2) and the second transistor (Q3) in the control unit (303) to be disconnected or connected, thus achieving control of the first switch unit (301) and the second switch unit (302), that is: controlling the first switch unit (301) to enable or disenable the first connection between the second end of the first resistor (R1) and the second input end of the first amplification module (10); and controlling the second switch unit (302) to enable or disenable the second connection between the output end of the second amplification module (20) and the second input end of the first amplification module (10).

As such, the control signal outputted by the single-chip microcomputer can be configured through software, thus achieving switch of different functions of the output signal from the output control circuit, thus further achieving intelligentization and remote configuration.

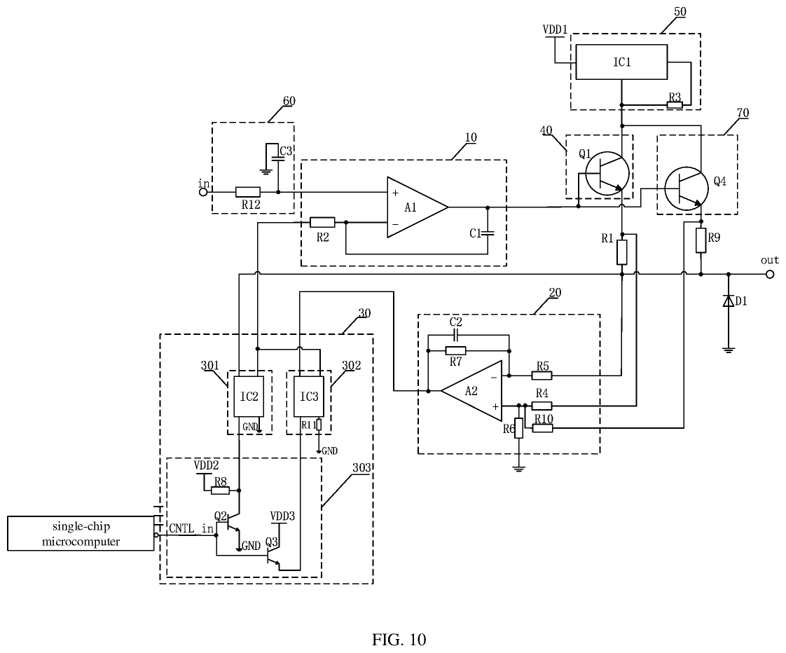

As shown in FIG. 10, the output control circuit (1) may further include a diode (D1) connected to the signal output end (out). In specific, a positive electrode of the diode (D1) is grounded (GND), and a negative electrode of the diode (D1) is connected to the signal output end (out). The diode (D1) is configured to absorb a peak voltage generated in response to the first solid-state relay (IC2) or the second solid-state relay (IC3) being disconnected.

As shown in FIGS. 7-10, the output control circuit (1) may further include a filtration module (60) arranged between the first amplification module (10) and the signal input end (in), where the first input end of the first amplification module (10) is connected to the signal input end (in) through the filtration module (60), by which the analog quantity of the voltage input signal is filtered; the filtered analog quantity of the voltage input signal is inputted into the first input end of the first amplification module (10). In specific, the filtration module (60) may include a twelfth resistor (R12) and a third capacitor C3.

According to embodiments of the present disclosure, the output control circuit, by means of the control signal of the control unit (303), controls the first switch unit (301) (specifically may be the first solid-state relay (IC2)) in the switch module (30) to enable or disenable the first connection between the second end of the first resistor (R1) and the second input end of the first amplification module (10); and controls the second switch unit (302) (specifically may be the second solid-state relay (IC3)) to enable or disenable the second connection between the output end of the second amplification module (20) and the second input end of the first amplification module (10).

When the control signal is a low-level signal, both the first transistor (Q2) and the second transistor (Q3) in the control unit (303) are turned off, so that the first switch unit (301) (specifically may be the first solid-state relay (IC2)) are turned on, and the second switch unit (302) (specifically may be the second solid-state relay (IC3)) are turned off, thus enabling the first connection between the second end of the first resistor (R1) and the second input end of the first amplification module (10); while disenabling the second connection between the output end of the second amplification module (20) and the second input end of the first amplification module (10). As shown in FIG. 7, in this circumstance, the output control circuit is in a voltage feedback mode.

As an example, when it is required to output the analog quantity of the second voltage output signal (such as the voltage output signal at 0-10 V) from the signal output end (out), the control signal input end (CNTL-in) is inputted with the low-level signal; the voltage input signal inputted from the signal input end (in) is controlled to be the voltage input signal with the analog quantity at 0-10 V; so that the first connection between the second end of the first resistor (R1) and the second input end of the first amplification module (10) is enabled; while the second connection between the output end of the second amplification module (20) and the second input end of the first amplification module (10) is disenabled, accordingly the first amplification module (10) and the first triode (Q1) constitute the emitter follower circuit. Thus, by means of a voltage feedback function, the analog quantity of the second voltage output signal (such as the voltage output signal at 0-10 V) is outputted from the signal output end (out).

As another example, when it is required to output the digital quantity of the first voltage output signal (such as the voltage output signal at 12 V) from the signal output end (out), the control signal input end (CNTL-in) is inputted with the low-level signal; the voltage input signal inputted from the signal input end (in) is controlled to be the voltage input signal with the digital quantity at 12 V; so that the first connection between the second end of the first resistor (R1) and the second input end of the first amplification module (10) is enabled; while the second connection between the output end of the second amplification module (20) and the second input end of the first amplification module (10) is disenabled, accordingly the first amplification module (10) and the first triode (Q1) constitute the emitter follower circuit. Thus, by means of the voltage feedback function, the digital quantity of the first voltage output signal (such as the voltage output signal at 12 V) is outputted from the signal output end (out).

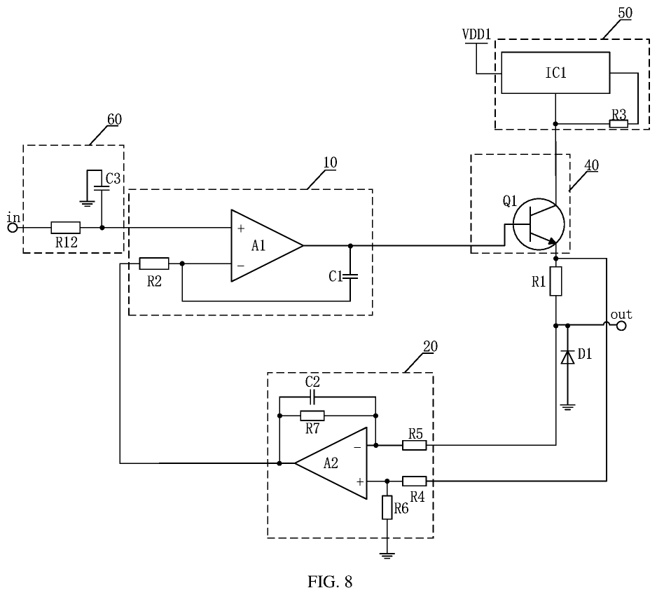

When the control signal is a high-level signal, the first transistor (Q2) and the second transistor (Q3) in the control unit (303) each are turned on, so that the first switch unit (301) (specifically may be the first solid-state relay (IC2)) are turned off, and the second switch unit (302) (specifically may be the second solid-state relay (IC3)) are turned on, thus disenabling the first connection between the second end of the first resistor (R1) and the second input end of the first amplification module (10); and enabling the second connection between the output end of the second amplification module (20) and the second input end of the first amplification module (10). As shown in FIG. 8, in this circumstance, the output control circuit is in a current feedback mode.

20) For example, when it is required to output the analog quantity of the current output signal (such as the current output signal at 0-20 mA) from the signal output end (out), the control signal input end (CNTL-in) is inputted with the high-level signal; the voltage input signal inputted from the signal input end (in) is controlled to be the voltage input signal with the analog quantity at 0-10 V; and the first connection between the second end of the first resistor (R1) and the second input end of the first amplification module (10) is disenabled; while the second connection between the output end of the second amplification module (20) and the second input end of the first amplification module (10) is enabled. In this circumstance, the output control circuit is in the current feedback mode, where the voltage signals across the first resistor (R1) are subjected to differential amplification by passing through the second amplification module (20) (specifically may be the second operational amplifier (A2); and the resulting amplified voltage is required to be consistent with an input voltage corresponding to the voltage input signal. For example, based on that the first resistor (R1), the fourth resistor (R4), the fifth resistor (R5) and the seventh resistor (R7) each are 10Ω, in response to requiring the signal output end (out) to output a current with the analog quantity at 20 mA, with the input voltage of U=R1*I*Af=10*0.02*100/2V=10V, the second amplification module (20) is of an amplification factor is 50-fold; and based on that the first resistor (R1), the fourth resistor (R4), the fifth resistor (R5) and the seventh resistor (R7) each are 5Ω, the second amplification module (20) is of the amplification factor is 100-fold.

On the basis of the above embodiments, when a single triode (i.e., the first triode (Q1)) is insufficient to drive the desired current, the output control circuit may include two triodes connected in parallel. In an embodiment of the present disclosure as shown in FIG. 10, the output control circuit may further include a second power module (70) and a ninth resistor (R9). In specific, the second power module (70) may be composed of a triode or a Metal-Oxide-Semiconductor (MOS) transistor, which is not limited herein particularly. In the embodiment of the present disclosure, the output control circuit is illustrated by taking second triode (Q4) serving as the second power module (70) as an example, where a base electrode of the second triode (Q4) serves as a first end of the second power module (70); a collecting electrode of the second triode (Q4) serves as a second end of the second power module (70); and an emitting electrode of the second triode (Q4) serves as a third end of the second power module (70). A control end (i.e., the base electrode) of the second triode (Q4) is connected to the output end of the first amplification module (10); and a first end (i.e., the collecting electrode) of the second triode (Q4) is connected to the first end (i.e., the collecting electrode) of the first triode (Q1). A first end of the ninth resistor (R9) is connected to a second end (i.e., an emitting electrode) of the second triode (Q4); and a second end of the ninth resistor (R9) is connected to the signal output end (out).

Correspondingly, the second amplification module (20) may further include: a tenth resistor (R10). In specific, a first end of the tenth resistor (R10) is connected to the first end of the ninth resistor (R9); and a second end of the tenth resistor (R10) is connected to the non-inverting input end of the second operational amplifier (A2).

It should be noted that, the output control circuit as shown in FIG. 10 operates in a same principle as the output control circuit as shown in FIG. 9, which is not elaborated here.

In summary, according to embodiments of the present disclosure, the output control circuit includes: the signal output end, the signal input end, the first amplification module, the first power module, the first resistor, the second amplification module and the switch module; the voltage input signal is inputted from the signal input end; the first input end of the first amplification module is connected to the signal input end; the first end of the first power module is connected to the output end of the first amplification module; the second end of the first power module is connected to the first direct-current voltage source; the first end of the first resistor is connected to the third end of the first power supply; the second end of the first resistor is connected to the signal output end; the first input end of the second amplification module is connected to the first end of the first resistor; the second input end of the second amplification module is connected to the second end of the first resistor; the switch module is connected to the second end of the first resistor, the output end of the second amplification module, and the second input end of the first amplification module, respectively; the switch module is configured to switch between the first connection and the second connection, where the first connection is between the second end of the first resistor and the second input end of the first amplification module, while the second connection is between the output end of the second amplification module and the second input end of the first amplification module; and the digital quantity of the first voltage output signal, the analog quantity of the second voltage output signal, and the analog quantity of the current output signal are outputted from the signal output end. As such, the output control circuit further achieves intelligentization and remote configuration by software control, thus enabling the controller to switch different functions of the output signal, and enhancing universality, safety, and reliability for the output control circuit.

To implement the above embodiments, the present disclosure further provides in embodiments a controller

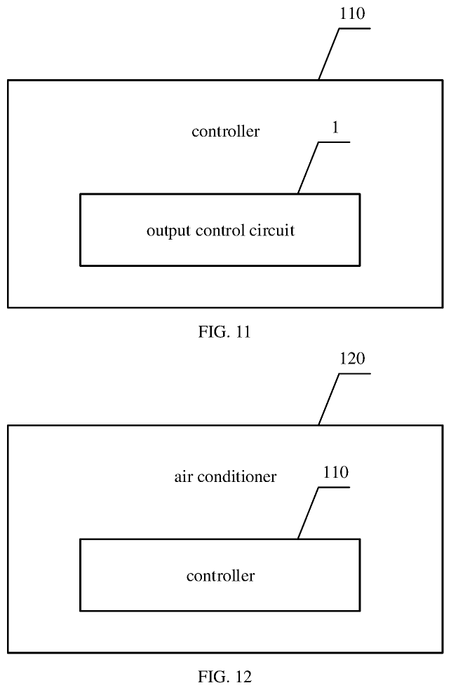

As shown in FIG. 11, the present disclosure provides in embodiments a controller (110), which specifically includes: the output control circuit (1) in any embodiment as described above.

According to embodiments of the present disclosure, the controller further achieves intelligentization and remote configuration by software control, thus enabling the controller to switch different functions of the output signal, and enhancing universality, safety, and reliability for the output control circuit.

To implement the above embodiments, the present disclosure further provides in embodiments an air conditioner (120).

As shown in FIG. 12, the present disclosure provides in embodiments an air conditioner (120), which specifically includes the controller (110) as shown in FIG. 11.

According to embodiments of the present disclosure, the air conditioner further achieves intelligentization and remote configuration by software control, thus enabling the controller to switch different functions of the output signal, and enhancing universality, safety, and reliability for the output control circuit.

Reference throughout this specification to “an embodiment”, “some embodiments”, “one embodiment”, “another example”, “an example”, “a specific example” or “some examples” means that a particular feature, structure, material, or characteristic described in connection with the embodiment or example is included in at least one embodiment or example of the present disclosure. Thus, the appearances of the phrases such as “in some embodiments”, “in one embodiment”, “in an embodiment”, “in another example”, “in an example”, “in a specific example”, or “in some examples” in various places throughout this specification are not necessarily referring to the same embodiment or example of the present disclosure. Furthermore, the particular features, structures, materials, or characteristics may be combined in any suitable manner in one or more embodiments or examples. In addition, those skilled in the art can combine different embodiments or examples described, as well as the features in different embodiments or examples as described in the present disclosure without mutual contradiction.

Although explanatory embodiments have been shown and described, it would be appreciated by those skilled in the art that the above embodiments cannot be construed to limit the present disclosure, and changes, alternatives, and modifications can be made in the embodiments in the scope of the present disclosure.

1. An output control circuit, wherein the output control circuit is arranged in a controller, and the output control circuit comprises:
a signal input end, configured to input a voltage input signal;
a first amplification module, wherein a first input end of the first amplification module is connected to the signal input end;
a first power module, wherein a first end of the first power module is connected to an output end of the first amplification module; and a second end of the first power module is connected to a first direct-current voltage source;
a first resistor, wherein a first end of the first resistor is connected to a third end of the first power module;
a second amplification module, wherein a first input end of the second amplification module is connected to the first end of the first resistor; and a second input end of the second amplification module is connected to a second end of the first resistor;
a switch module, wherein the switch module is connected to the second end of the first resistor, an output end of the second amplification module, and a second input end of the first amplification module, respectively; and the switch module is configured to switch between a first connection and a second connection, wherein the first connection is between the second end of the first resistor and the second input end of the first amplification module; and the second connection is between the output end of the second amplification module and the second input end of the first amplification module; and
a signal output end, wherein the signal output end is connected to the second end of the first resistor, and configured to output a digital quantity of a first voltage output signal, an analog quantity of a second voltage output signal, and an analog quantity of a current output signal.

2. The output control circuit according to claim 1, wherein the first amplification module comprises:
a first operational amplifier, wherein a non-inverting input end of the first operational amplifier is connected to the signal input end; and an output end of the first operational amplifier is connected to the first end of the first power module;
a first capacitor, wherein a first end of the first capacitor is connected to the output end of the first operational amplifier, and a second end of the first capacitor is connected to an inverting input end of the first operational amplifier; and
a second resistor, wherein a first end of the second resistor is connected to the inverting input end of the first operational amplifier, and a second end of the second resistor is connected to the switch module.

3. The output control circuit according to claim 1, further comprising an overcurrent protection module, wherein the second end of the first power module is connected to the first direct-current voltage source through the overcurrent protection module.

4. The output control circuit according to claim 3, wherein the overcurrent protection module comprises:
a voltage stabilizer or current limiter, wherein a first end of the voltage stabilizer or current limiter is connected to the first direct-current voltage source; and a second end of the voltage stabilizer or current limiter is connected to the second end of the first power module; and
a third resistor, wherein the second end of the voltage stabilizer or current limiter is connected to a third end of the voltage stabilizer or current limiter through the third resistor.

5. The output control circuit according to claim 1, wherein the second amplification module comprises:
a fourth resistor;
a fifth resistor;
a second operational amplifier, wherein a non-inverting input end of the second operational amplifier is connected to the first end of the first resistor through the fourth resistor; an inverting input end of the second operational amplifier is connected to the second end of the first resistor through the fifth resistor; and an output end of the second operational amplifier is connected to the switch module;
a sixth resistor, wherein a first end of the sixth resistor is grounded; a second end of the sixth resistor is connected to the non-inverting input end of the second operational amplifier;
a seventh resistor, wherein a first end of the seventh resistor is connected to the output end of the second operational amplifier; and a second end of the seventh resistor is connected to the inverting input end of the second operational amplifier; and
a second capacity, wherein a first end of the second capacitor is connected to the output end of the second operational amplifier; and a second end of the second capacitor is connected to the inverting input end of the second operational amplifier.

6. The output control circuit according to claim 1, wherein the switch module comprises:
a first switch unit, wherein the first switch unit is connected to the second end of the first resistor and the second input end of the first amplification module, respectively;
a second switch unit, wherein the second switch unit is connected to the output end of the second amplification module and the second input end of the first amplification module, respectively; and
a control unit, wherein the control unit is connected to the first switch unit and the second switch unit, respectively; the control unit is configured to: in response to a control signal inputted,
control the first switch unit to enable or disenable the first connection between the second end of the first resistor and the second input end of the first amplification module; or
control the second switch unit to enable or disenable the second connection between the output end of the second amplification module and the second input end of the first amplification module.

7. The output control circuit according to claim 6, wherein the first switch unit comprises a first solid-state relay, wherein an input end of the first solid-state relay is connected to the second end of the first resistor; an output end of the first solid-state relay is connected to the second input end of the first amplification module; an input control end of the first solid-state relay is connected to the control unit; and an output control end of the first solid-state relay is grounded.

8. The output control circuit according to claim 6 or 7, wherein the second switch unit comprises a second solid-state relay, wherein an input end of the second solid-state relay is connected to the output end of the second amplification module; an output end of the second solid-state relay is connected to the second input end of the first amplification module; an input control end of the second solid-state relay is connected to the control unit; and an output control end of the second solid-state relay is grounded.

9. The output control circuit according to claim 6, wherein the control unit comprises:
a control signal input end, configured to input the control signal;
a first transistor, wherein a control end of the first transistor is connected to the control signal input end; a first end of the first transistor is connected to the first switch unit; and a second end of the first transistor is grounded;
an eighth resistor, wherein a first end of the eighth resistor is connected to a second direct-current voltage source; and a second end of the eighth resistor is connected to the first end of the first transistor; and
a second transistor, wherein a control end of the second transistor is connected to the control signal input end; a first end of the second transistor is connected to a third direct-current voltage source; and a second end of the second transistor is connected to the second switch unit.

10. The output control circuit according to claim 1, further comprising a diode, wherein a positive electrode of the diode is grounded; and a negative electrode of the diode is connected to the signal output end.

11. The output control circuit according to claim 1, further comprising a filtration module, wherein the first input end of the first amplification module is connected to the signal input end through the filtration module.

12. The output control circuit according to claim 5, further comprising:
a second power module, wherein a first end of the second power module is connected to the output end of the first amplification module; and a second end of the second power module is connected to the second end of the first power module; and
a ninth resistor, wherein a first end of the ninth resistor is connected to a third end of the second power module; and a second end of the ninth resistor is connected to the signal output end,
wherein the second amplification module further comprises:
a tenth resistor, wherein a first end of the tenth resistor is connected to the first end of the ninth resistor; and a second end of the tenth resistor is connected to the non-inverting input end of the second operational amplifier.

13. A controller, comprising the output control circuit according to claim 1.

14. An air conditioner, comprising the controller according to claim 13.
